(19) United States
(12) Patent Application Publication
(10) Pub. No.: US 2024/0314940 A1
(43) Pub. Date: Sep. 19, 2024

(54) PACKAGING SUBSTRATES HAVING RINGLESS VIAS

(71) Applicant: SKYWORKS SOLUTIONS, INC., Irvine, CA (US)

(72) Inventors: Ki Wook LEE, Irvine, CA (US); Chien Jen WANG, Taoyuan City (TW)

(21) Appl. No.: 18/604,301

(22) Filed: Mar. 13, 2024

Related U.S. Application Data
(60) Provisional application No. 63/453,027, filed on Mar. 17, 2023.

(51) Int. Cl. H05K 3/42; H05K 1/11; H05K 3/00

(52) U.S. Cl. CPC H05K 3/429; H05K 1/115; H05K 3/0047; H05K 2201/09518; H05K 2201/09545; H05K 2203/107

(57) ABSTRACT

According to certain aspects, devices and methods can be provided for forming packaging substrates having ringless vias. For instance, a method of forming one or more vias in a packaging substrate can include: laminating a plurality of layers of a packaging substrate; drilling a via hole through the plurality of layers using a through drill, the plurality of layers not including a capture pad or ring along a path of the through drill for drilling the via hole; and forming a via in the via hole using a plating process.

### CROSS-REFERENCE TO RELATED APPLICATION(S)

This application claims the benefit of U.S. Provisional Application No. 63/453,027, filed Mar. 17, 2023, entitled “PACKAGING SUBSTRATES HAVING RINGLESS VIAS,” which is incorporated herein by reference in its entirety.

### BACKGROUND

### Field

The present disclosure generally relates to substrates, for example, for packaged electronic modules.

### Description of the Related Art

In many electronics applications, integrated circuits and/or circuit elements are implemented as parts of packaged modules. A packaged module typically includes a substrate configured to receive and support a plurality of components such as semiconductor die and/or circuit elements such as discrete passive components.

### SUMMARY

According to some implementations, the present disclosure relates to a method of forming one or more vias in a packaging substrate. The method can include laminating a plurality of layers of a packaging substrate, drilling a via hole through the plurality of layers using a through drill, the plurality of layers not including a capture pad or ring along a path of the through drill for drilling the via hole, and forming a via in the via hole using a plating process.

In some examples, the through drill is configured to drill through all of the laminated plurality of layers. In some cases, the through drill includes a mechanical drill. In other cases, the through drill includes a laser drill. In certain examples, the via is configured to reduce signal reflection of analog signals along a path of the via.

In certain examples, the method can further include forming a plurality of stacked vias in the packaging substrate. In some cases, the plating process includes copper plating. In some examples, the packaging substrate includes one or more layers in addition to the plurality of layers, and the via does not extend through the one or more layers.

According to certain implementations, the present disclosure relates to a method of forming one or more vias in a packaging substrate. The method can include laminating a plurality of layers of a packaging substrate, drilling a via hole through the plurality of layers using a through drill, the plurality of layers not including a feature along a path of the through drill for drilling the via hole, and forming a via in the via hole using a plating process.

According to some implementations, the present disclosure relates to a packaging substrate. The packaging substrate can include a plurality of laminated layers. The packaging substrate can also include a via extending through the plurality of laminated layers, the via not including a capture pad or ring along a path of the via through the plurality of laminated layers.

In some examples, the via is formed by applying a through drill that is configured to drill through all of the plurality of laminated layers. In some cases, the through drill includes a mechanical drill. In other cases, the through drill includes a laser drill. In certain examples, the via is configured to reduce signal reflection of analog signals along the path of the via.

In certain examples, the plurality of laminated layers is laminated at the same time. In some examples, the packaging substrate further includes a plurality of stacked vias. In certain examples, the vias may be formed by a plating process. In some cases, the plating process includes copper plating. In some examples, the packaging substrate includes one or more layers in addition to the plurality of layers, and the via does not extend through the one or more layers.

According to some implementations, the present disclosure relates to a packaging substrate. The packaging substrate can include a plurality of laminated layers. The packaging substrate can also include a via extending through the plurality of laminated layers, the via not including a feature along a path of the via through the plurality of laminated layers.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates a block diagram illustrating a side view of a packaging substrate, in accordance with one or more embodiments.

FIG. 2 is a diagram illustrating a side view of a packaging substrate, in accordance with one or more embodiments.

FIG. 3 shows a side view of a packaging substrate having one or more features as described herein, in accordance with one or more embodiments.

FIGS. 4A to 4B show various stages of a process that can be implemented to fabricate a packaging substrate similar to the packaging substrate of FIGS. 1 and 2, in accordance with one or more embodiments.

FIGS. 5A to 5C show various stages of a process that can be implemented to fabricate a packaging substrate similar to the packaging substrate of FIG. 3, in accordance with one or more embodiments.

FIG. 6 shows a process that can be implemented to fabricate a packaging substrate and/or ringless vias having one or more features as described herein, in accordance with one or more embodiments.

FIG. 7 depicts an example wireless device having one or more advantageous features described herein, in accordance with one or more embodiments.

### DETAILED DESCRIPTION

The headings provided herein, if any, are for convenience only and do not necessarily affect the scope or meaning of the claimed invention.

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. For example, one or more components can be mounted on the upper side of the packaging substrate, and an upper overmold can be provided to encapsulate such components. One or more components may also be mounted on the lower side of the packaging substrate, and a lower overmold can be provided to encapsulate such components. In some embodiments, a packaged module can be a dual-sided module.

A packaging substrate can include a plurality of layers, and one or more conductive features, such as conductive vias, may be provided through one or more of the layers in order to provide electrical connection. In some cases, stacked vias can be implemented in the plurality of layers of the packaging substrate. For example, a laser drill can be used to drill holes through the layers of the packaging substrate, and vias can be formed in the layers. For instance, a layer of the packaging substrate can be laminated and drilled to form a via. Then, another layer of the packaging substrate can be laminated and drilled to form a via. A via can be formed through a layer by drilling with a laser drill to a capture pad or ring. However, presence of capture pads or rings can lead to signal reflection in the signal path, for example, due to pad size variation, via size vibration, via to pad alignment, etc. Therefore, according to certain aspects, a mechanical drill that can drill through the packaging substrate can be applied such that a through via can be formed without using capture pads or rings.

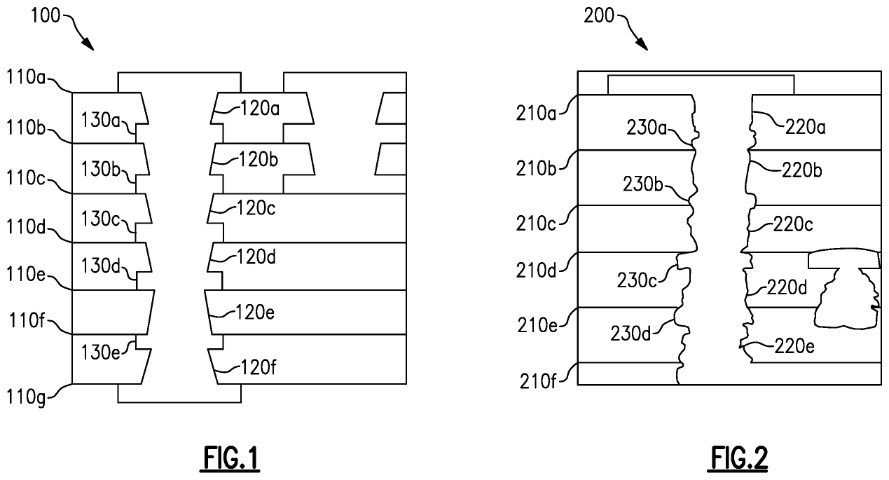

FIG. 1 is a block diagram illustrating a side view of a packaging substrate 100. For instance, a packaging substrate can be a printed circuit board (PCB). The packaging substrate 100 can include a plurality of layers 110. For example, the plurality of layers 110 can be conductive layers. A plurality of stacked vias 120 can be formed through the layers 110. In some embodiments, the stacked vias 120 can be microvias formed by laser, for example, in connection with a high density interconnect (HDI) packaging substrate. Capture pads or rings 130 can be used for drilling via holes to form the vias 120. For instance, capture pads or rings 130 can be used for inner layers 110. The vias 120 can have any suitable shape. The capture pads or rings 130 can also have any suitable shape. The packaging substrate 100 can also include other layers and features, such as dielectric layers, passive components (such as resistors, capacitors, and inductors), conductor features (such as vias and traces), and a ground plane.

In the example of FIG. 1, the packaging substrate 100 includes layers 110a-g, and vias 120a-f are formed through the layers 110a-g. Capture pads 130a-e can be used for drilling via holes to form the vias 120a-f. Stacked vias 120 can be formed layer by layer. For example, a layer 120d can be laminated, and a via hole can be drilled in the layer 120d to a capture pad 130d using a laser drill. The via 120d can be formed in the via hole, for example, using copper plating technology. Then, a layer 120c can be laminated, and a via hole can be drilled in the layer 120c to a capture pad 130c using a laser drill. The via 120c can be formed in the via hole. The process can be repeated for other layers 120a, b, e, f.

Capture pads 130 can be used to drill to target locations in the layers 110. For instance, a capture pad 130 may indicate a target location in an inner layer 110 to which to drill a via hole. Capture pads 130 can be used for drill alignment across different layers 110. In general, the size of the capture pads 130 can be larger than the size of corresponding vias 120. The size of a capture pad 130 and/or a via 120 can refer to a diameter, one or more dimensions, etc. as appropriate. In some cases, the size of the capture pads 130 can be minimized, for example, to be similar to the size of the vias 120. However, as shown in the example of FIG. 1, at least some portions of the capture pads 130 protrude horizontally, along the signal path of the vias 120. For instance, portions of the capture pads 130 can still protrude in the horizontal or x- or y-direction along the signal path of the vias 120 in the vertical or z-direction due to pad size variation, via size variation, via-to-pad alignment, etc. In some embodiments, these protruding portions may also be referred to as “rings.” Presence of the capture pads or rings 130 can cause signal reflection along the signal path, for example, for analog signals. Accordingly, signal transmission performance can be impacted. For instance, such rings can create an inconsistent diameter for the signal path, and in addition, rings may not be uniform for different layers 110.

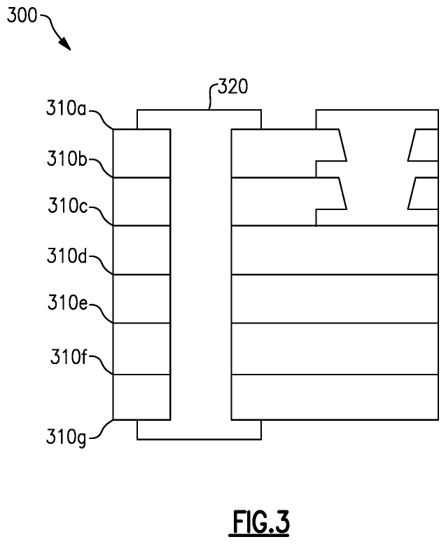

FIG. 2 is a diagram illustrating a side view of a packaging substrate 200. Similar to FIG. 1, stacked vias 220 can be formed in layers 210 of the packaging substrate 200 using capture pads or rings 230. As in FIG. 1, portions of capture pads or rings 230 can be seen around the vias 220. Such capture pads or rings 230 can cause signal reflection along the signal path and reduce signal transmission performance.

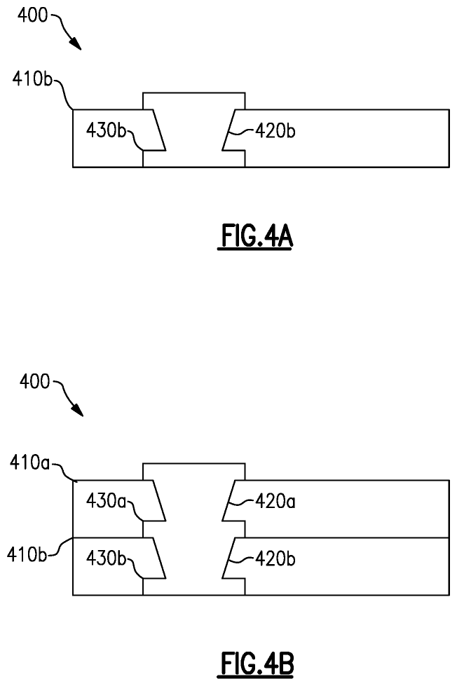

FIG. 3 shows a side view of a packaging substrate 300 having one or more features as described herein. The packaging substrate 300 can include a plurality of layers 310. For example, the plurality of layers 310 can indicate conductive layers. The packaging substrate 300 can also include other layers and features, such as dielectric layers, passive components (such as resistors, capacitors, and inductors), conductor features (such as vias and traces), and a ground plane.

In the example of FIG. 3, the packaging substrate 300 includes layers 310a-g. Instead of forming stacked vias layer by layer, a via hole can be drilled through all the layers 310 using a through drill such that capture pads or rings do not need to be used in the layers 310. For example, a via hole can be drilled through all the layers 310 in the vertical or z-direction at once or continuously with a mechanical drill. According to certain aspects, a through drill may refer to a drill that can drill through all layers of a packaging substrate, for example, at once or continuously. A through drill can drill through all layer of a packaging substrate in a vertical or z-direction. A through drill can drill through the layers from top-to-bottom or bottom-to-top, for example, depending on orientation the packaging substrate. Examples of a through drill can include a mechanical drill, a laser drill, a chemical drill, or any other suitable drill that can drill through all of layers of a packaging substrate.

When applying a through drill, lamination of all layers 310 can be completed, and then a via hole can be drilled through all the layers 310. A via 320 can be formed in the via hole, for example, by copper plating technology. For instance, the via hole can be filled with copper to form the via 320. The via 320 can have any suitable shape. Since a through drill can drill through all the layers 310, capture pads or rings are not used to form the via 320. There are no capture pads or rings around the via 320, and in some embodiments, the via 320 may be referred to as a ringless via. For instance, the via 320 does not have any features along the signal path or on the wall(s) of the via 320. A smoother signal path can be provided by the via 320 compared to vias formed using capture pads or rings. Accordingly, signal reflection due to capture pads or rings can be reduced, and better signal transmission performance can be provided.

In the example of FIG. 3, a through drill is applied to the packaging substrate 300 to drill a via hole through all the layers 310a-g. The layers 310a-g are laminated. Then, the through drill can be used to drill a via hole through the layers 310a-g. For instance, the through drill is applied through the layers 310a-g continuously to create the via hole. The via hole can be filled by a plating process to form a via 320. As an example, copper plating technology can be used. Capture pads or rings are not necessary for forming the via hole and the via 320 since the through drill can drill through the layers 310a-g at once.

In some embodiments, application of the through drill and via holes without capture pads or rings can be implemented only in desired portions of the packaging substrate 300. For example, the through drill can be used in a particular section of the packaging substrate 300 to form a via hole without capture pads, and other sections of the packaging substrate 300 can include stacked vias or other types of vias. In certain embodiments, the through drill can drill through some layers 310, but not all layers 310 of the packaging substrate 300. The through drill can be configured to drill through at least the desired layers. For instance, the through drill can drill a via hole through layers 310a and 310b without capture pads, but not rest of the layers 310c-g. As an example, a mechanical drill or a laser drill may be used to drill through several but not all layers of the packaging substrate 300.

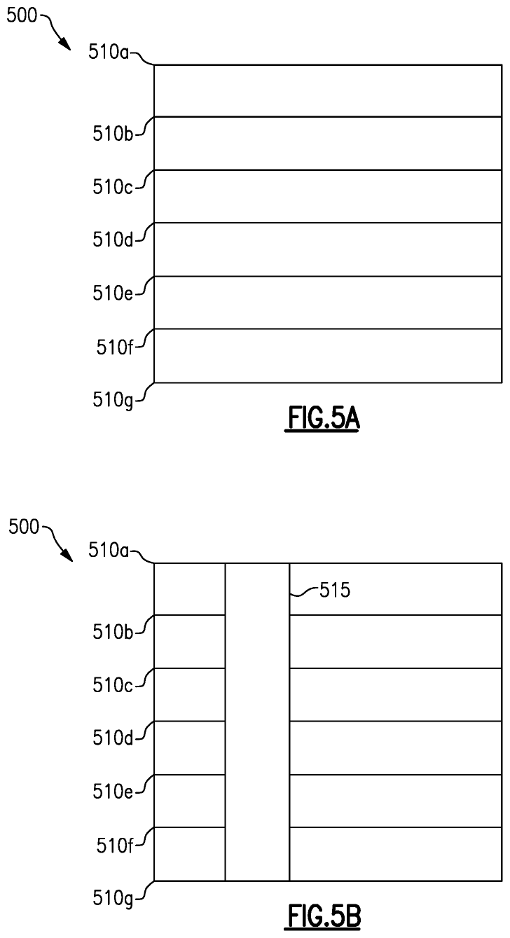

FIGS. 4A to 4B show various stages of a process that can be implemented to fabricate a packaging substrate similar to the packaging substrate 100, 200 of FIGS. 1 and 2.

In FIGS. 4A-4B, layers 410 of a packaging substrate 400 can be laminated and drilled layer by layer in order to form stacked vias 420.

In FIG. 4A, a layer 410b of a packaging substrate 400 is laminated and drilled to form a via 420b. A laser drill may be used to drill a via hole through the layer 410b to a capture pad 430b. The via 420b can be formed using copper plating technology.

In FIG. 4B, a layer 410a of the packaging substrate 400 is laminated and drilled to form a via 420a. A laser drill may be used to drill a via hole through the layer 410a to a capture pad 430a. The via 420a can be formed using copper plating technology.

Additional layers can be laminated and drilled to form additional stacked vias. As shown in FIGS. 4A-4B, capture pads 430 can create rings along the signal path of the vias 420, which can lead to signal reflection along the signal path.

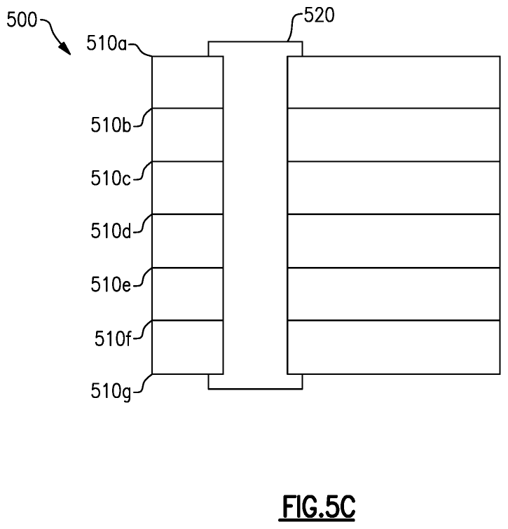

FIGS. 5A to 5C show various stages of a process that can be implemented to fabricate a packaging substrate similar to the packaging substrate 300 of FIG. 3.

In FIGS. 5A-5C, layers 510 of a packaging substrate 500 can be laminated, and all layers 510 can be drilled together with a through drill to form a via 520.

In FIG. 5A, layers 510a-g are laminated. In FIG. 5B, a through drill is applied to the layers 510a-g to drill a via hole 515 through all the layers 510a-g. For example, the via hole 515 can be drilled through all the layers 510a-g at once or continuously. In FIG. 5C, the via hole 515 can be filled with copper using plating technology to form a via 520. Capture pads or rings are not used in the process since all the layers 510a-g can be drilled together. In this way, ringless vias can be formed in a packaging substrate, and there are no features along the signal path and/or the wall(s) of the via 520. Accordingly, signal reflection along the signal path of the via 520 can be reduced for analog signals, and electrical performance can be improved.

As described above, in some embodiments, a through drill can be applied through some but not all layers 510 of the packaging substrate 500. For example, the through drill can be applied to two or more layers 510 to form a via. In certain embodiments, ringless vias can be implemented only in some portions of the packaging substrate 500, and other portions of the packaging substrate 500 can include stacked vias. A mechanical drill, a laser drill, a chemical drill, or another appropriate drill can be used as a through drill, depending on the embodiment.

Ringless vias can be formed in a packaging substrate as described herein in order to reduce signal reflection and improve performance. Layers of a packaging substrate can be laminated together, then drilled together with a through hole drill to form a via hole. This can eliminate use of capture pads or rings, or other features, for drilling through multiple layers. Not having capture pads or rings, or other features, on the via can reduce signal reflection along the signal path and increase signal transmission performance.

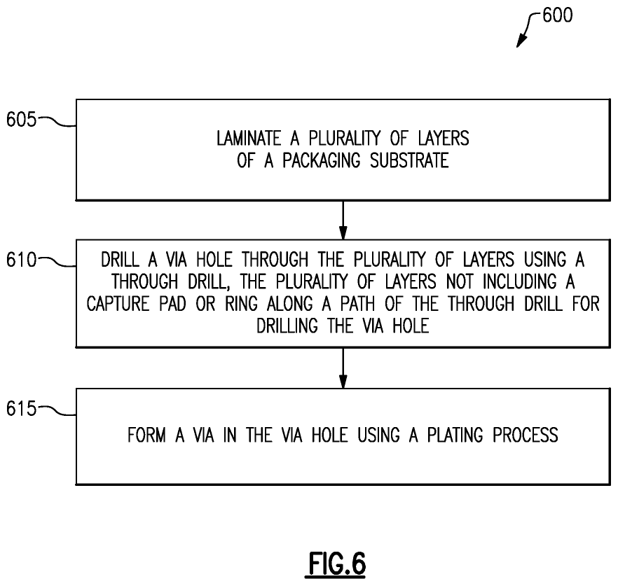

FIG. 6 shows a process 600 that can be implemented to fabricate a packaging substrate and/or ringless vias having one or more features as described herein. Certain details relating to the process 600 are explained in more detail with respect to FIGS. 1-5. Depending on the embodiment, the process 600 may include fewer or additional blocks, and the blocks may be performed in an order that is different from illustrated.

At block 605, the process 600 can laminate a plurality of layers of a packaging substrate. For example, the plurality of layers can be laminated together or at the same time.

At block 610, the process 600 can drill a via hole through the plurality of layers using a through drill, the plurality of layers not including a capture pad or ring along a path of the through drill for drilling the via hole. In some embodiments, the plurality of layers does not include any features along a path of the through drill for drilling the via hole. The through drill can be configured to drill through all of the plurality of layers. The through drill can include one or more of: a mechanical drill or a laser drill.

At block 615, the process 600 can form a via in the via hole using a plating process. The via can be configured to reduce signal reflection of analog signals along a path of the via. The plating process can include copper plating. The via does not include a capture pad or ring or a feature on the wall(s) of the via.

In some embodiments, the process 600 can also include forming a plurality of stacked vias in the packaging substrate. For example, the plurality of stacked vias can be formed in other portions of the packaging substrate. In certain embodiments, the packaging substrate can include one or more layers in addition to the plurality of layers, and the via does not extend through the one or more layers. For instance, the through drill can be used to drill a hole through some layers of the packaging substrate, but not all layers of the packaging substrate.

A packaging substrate including ringless vias as described herein can be used to provide packaged modules, such as dual-sided modules. Examples related to upper side and/or lower side configurations of packaged modules, as well as examples related to fabrication methods where a plurality of units can be fabricated in an array format, are described in U.S. Publication No. 2022/0319968, entitled “MODULE HAVING DUAL SIDE MOLD WITH METAL POSTS” and U.S. Publication No. 2018/0096949, entitled “DUAL-SIDED RADIO-FREQUENCY PACKAGE WITH OVERMOLD STRUCTURE,” each of which is hereby expressly incorporated by reference in its entirety. In some embodiments, at least some of the examples provided in U.S. Publication No. 2022/0319968 and U.S. Publication No. 2018/0096949 can utilize packaging substrates and/or ringless vias having one or more features as described herein.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

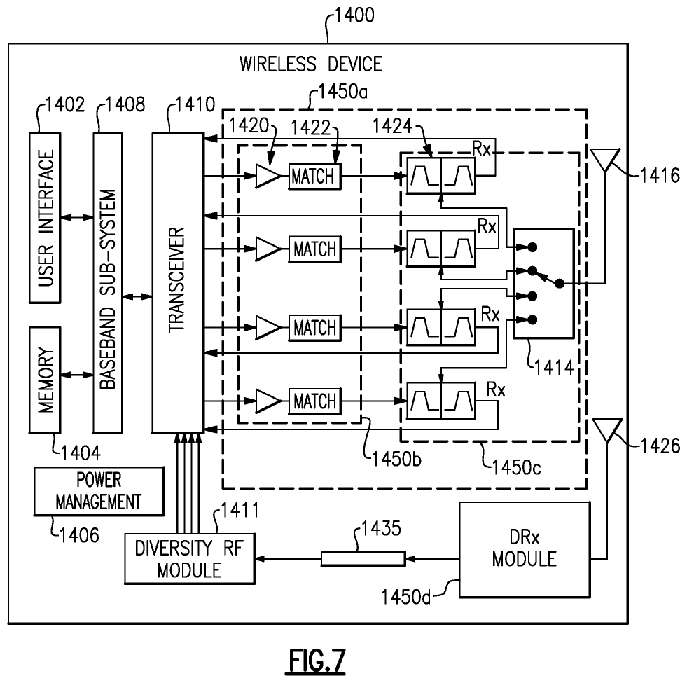

FIG. 7 depicts an example wireless device 1400 having one or more advantageous features described herein. In the example of FIG. 7, an RF module having one or more features as described herein can be implemented in a number of places. For example, an RF module may be implemented as a front-end module (FEM) indicated as 1450a. In another example, an RF module may be implemented as a power amplifier module (PAM) indicated as 1450b. In another example, an RF module may be implemented as an antenna switch module (ASM) indicated as 1450c. In another example, an RF module may be implemented as a diversity receive (DRx) module indicated as 1450d. It will be understood that an RF module having one or more features as described herein can be implemented with other combinations of components.

Referring to FIG. 7, power amplifiers (PAS) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 can also be in communication with a power management component 1406 that is configured to manage power for the operation of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example wireless device 1400, outputs of the PAs 1420 are shown to be matched (via respective match circuits 1422) and routed to their respective duplexers 1424. Such amplified and filtered signals can be routed to a primary antenna 1416 through an antenna switch 1414 for transmission. In some embodiments, the duplexers 1424 can allow transmit and receive operations to be performed simultaneously using a common antenna (e.g., primary antenna 1416). In FIG. 7, received signals are shown to be routed to “Rx” paths that can include, for example, a low-noise amplifier (LNA).

In the example of FIG. 7, the wireless device 1400 also includes the diversity antenna 1426 and the shielded DRx module 1450d that receives signals from the diversity antenna 1426. The shielded DRx module 1450d processes the received signals and transmits the processed signals via a transmission line 1435 to a diversity RF module 1411 that further processes the signal before feeding the signal to the transceiver 1410.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of forming one or more vias in a packaging substrate, the method comprising:
laminating a plurality of layers of a packaging substrate;
drilling a via hole through the plurality of layers using a through drill, the plurality of layers not including a capture pad or ring along a path of the through drill for drilling the via hole; and
forming a via in the via hole using a plating process.

2. The method of claim 1 wherein the through drill is configured to drill through all of the laminated plurality of layers.

3. The method of claim 1 wherein the through drill includes a mechanical drill.

4. The method of claim 1 wherein the through drill includes a laser drill.

5. The method of claim 1 wherein the via is configured to reduce signal reflection of analog signals along a path of the via.

6. The method of claim 1 further comprising forming a plurality of stacked vias in the packaging substrate.

7. The method of claim 1 wherein the plating process includes copper plating.

8. The method of claim 1 wherein the packaging substrate includes one or more layers in addition to the plurality of layers and wherein the via does not extend through the one or more layers.

9. A method of forming one or more vias in a packaging substrate, the method comprising:
laminating a plurality of layers of a packaging substrate;
drilling a via hole through the plurality of layers using a through drill, the plurality of layers not including a feature along a path of the through drill for drilling the via hole; and
forming a via in the via hole using a plating process.

10. The method of claim 9 wherein the through drill is configured to drill through all of the laminated plurality of layers.

11. A packaging substrate comprising:
a plurality of laminated layers; and
a via extending through the plurality of laminated layers, the via not including a capture pad or ring along a path of the via through the plurality of laminated layers.

12. The packaging substrate of claim 11 wherein the via is formed by applying a through drill that is configured to drill through all of the plurality of laminated layers.

13. The packaging substrate of claim 12 wherein the through drill includes a mechanical drill.

14. The packaging substrate of claim 12 wherein the through drill includes a laser drill.

15. The packaging substrate of claim 11 wherein the via is configured to reduce signal reflection of analog signals along the path of the via.

16. The packaging substrate of claim 11 wherein the plurality of laminated layers is laminated at the same time.

17. The packaging substrate of claim 11 wherein the packaging substrate further includes a plurality of stacked vias.

18. The packaging substrate of claim 11 wherein the via is formed by a plating process.

19. The packaging substrate of claim 18 wherein the plating process is copper plating.

20. The packaging substrate of claim 11 wherein the packaging substrate further includes one or more layers in addition to the plurality of laminated layers, and wherein the via does not extend through the one or more layers.
